(19) United States
(12) Patent Application Publication
(10) Pub. No.: US 2025/0095737 A1
(43) Pub. Date: Mar. 20, 2025

(54) MEMORY DEVICE

(71) Applicant: Kioxia Corporation, Tokyo (JP)

(72) Inventors: Kouji Matsuo, Ama Aichi (JP); Hiroshi Nakamura, Fujisawa Kanagawa (JP)

(73) Assignee: Kioxia Corporation, Tokyo (JP)

(21) Appl. No.: 18/789,095

(22) Filed: Jul. 30, 2024

(30) Foreign Application Priority Data
Sep. 20, 2023 (JP) 2023-153289

(51) Int. Cl. G11C 16/04; H10B 41/10; H10B 41/27; H10B 41/35; H10B 43/10; H10B 43/27; H10B 43/35

(52) U.S. Cl. CPC G11C 16/0483; H10B 41/10; H10B 41/27; H10B 41/35; H10B 43/10; H10B 43/27; H10B 43/35

(57) ABSTRACT

According to one embodiment, a memory device includes: a first semiconductor and a first insulator provided at a first position in a first direction intersecting a substrate; a first conductor extending in the first direction and having a first portion facing the first semiconductor without interposing the first insulator and a second portion facing the first insulator without interposing the first semiconductor; and a first charge storage film provided between the first portion and the first semiconductor and not provided between the second portion and the first insulator.

### CROSS-REFERENCE TO RELATED APPLICATIONS

This application is based upon and claims the benefit of priority from Japanese Patent Application No. 2023-153289, filed Sep. 20, 2023, the entire contents of which are incorporated herein by reference.

### FIELD

Embodiments described herein relate generally to a memory device.

### BACKGROUND

A NAND flash memory capable of storing data in a nonvolatile manner is known. In a memory device such as the NAND flash memory, a three-dimensional memory structure is adopted for high integration and large capacity.

### BRIEF DESCRIPTION OF THE DRAWINGS

FIG. 1 is a block diagram showing an example of a configuration of a memory system including a memory device according to an embodiment.

FIG. 2 is a circuit diagram showing an example of a circuit configuration of a memory cell array included in the memory device according to the embodiment.

FIG. 3 is a plan view showing an example of a planar layout of the memory cell array according to the embodiment.

FIG. 4 is a cross-sectional view taken along line IV-IV of FIG. 3, showing an example of a cross-sectional structure of the memory cell array according to the embodiment.

FIG. 5 is a cross-sectional view taken along line V-V of FIG. 4, showing an example of a cross-sectional structure of a memory cell transistor according to the embodiment.

FIG. 6 is a cross-sectional view taken along line VI-VI of FIG. 3, showing an example of a cross-sectional structure of the memory cell array according to the embodiment.

FIG. 7 is a cross-sectional view taken along line VII-VII of FIG. 6, showing an example of a cross-sectional structure of a select transistor according to the embodiment.

FIG. 8 is a plan view showing an example of a planar layout of the memory device according to the embodiment that is in the process of being manufactured.

FIG. 9 is a cross-sectional view showing an example of a cross-sectional structure of the memory device according to the embodiment that is in the process of being manufactured.

FIG. 10 is a plan view showing an example of the planar layout of the memory device according to the embodiment that is in the process of being manufactured.

FIG. 11 is a cross-sectional view showing an example of the cross-sectional structure of the memory device according to the embodiment that is in the process of being manufactured.

FIG. 12 is a plan view showing an example of the planar layout of the memory device according to the embodiment that is in the process of being manufactured.

FIG. 13 is a cross-sectional view showing an example of the cross-sectional structure of the memory device according to the embodiment that is in the process of being manufactured.

FIG. 14 is a plan view showing an example of the planar layout of the memory device according to the embodiment that is in the process of being manufactured.

FIG. 15 is a cross-sectional view showing an example of the cross-sectional structure of the memory device according to the embodiment that is in the process of being manufactured.

FIG. 16 is a plan view showing an example of the planar layout of the memory device according to the embodiment that is in the process of being manufactured.

FIG. 17 is a cross-sectional view showing an example of the cross-sectional structure of the memory device according to the embodiment that is in the process of being manufactured.

FIG. 18 is a plan view showing an example of the planar layout of the memory device according to the embodiment that is in the process of being manufactured.

FIG. 19 is a cross-sectional view showing an example of the cross-sectional structure of the memory device according to the embodiment that is in the process of being manufactured.

FIG. 20 is a plan view showing an example of the planar layout of the memory device according to the embodiment that is in the process of being manufactured.

FIG. 21 is a cross-sectional view showing an example of the cross-sectional structure of the memory device according to the embodiment that is in the process of being manufactured.

FIG. 22 is a plan view showing an example of the planar layout of the memory device according to the embodiment that is in the process of being manufactured.

FIG. 23 is a cross-sectional view showing an example of the cross-sectional structure of the memory device according to the embodiment that is in the process of being manufactured.

FIG. 24 is a plan view showing an example of the planar layout of the memory device according to the embodiment that is in the process of being manufactured.

FIG. 25 is a cross-sectional view showing an example of the cross-sectional structure of the memory device according to the embodiment that is in the process of being manufactured.

FIG. 26 is a plan view showing an example of the planar layout of the memory device according to the embodiment that is in the process of being manufactured.

FIG. 27 is a cross-sectional view showing an example of the cross-sectional structure of the memory device according to the embodiment that is in the process of being manufactured.

### DETAILED DESCRIPTION

In general, according to one embodiment, a memory device includes: a first semiconductor and a first insulator provided at a first position in a first direction intersecting a substrate; a first conductor extending in the first direction and having a first portion facing the first semiconductor without interposing the first insulator and a second portion facing the first insulator without interposing the first semiconductor; and a first charge storage film provided between the first portion and the first semiconductor and not provided between the second portion and the first insulator.

The embodiment will be described below with reference to the drawings. Dimensions and ratios of the drawings are not necessarily the same as actual ones.

In the following explanation, components having basically the same functions and structures will be referred to by the same reference symbols. In a case where components having similar configurations are particularly distinguished from each other, different characters or numbers may be added to the end of the same reference numeral.

### 1. Configuration

### 1.1 Configuration of Memory System

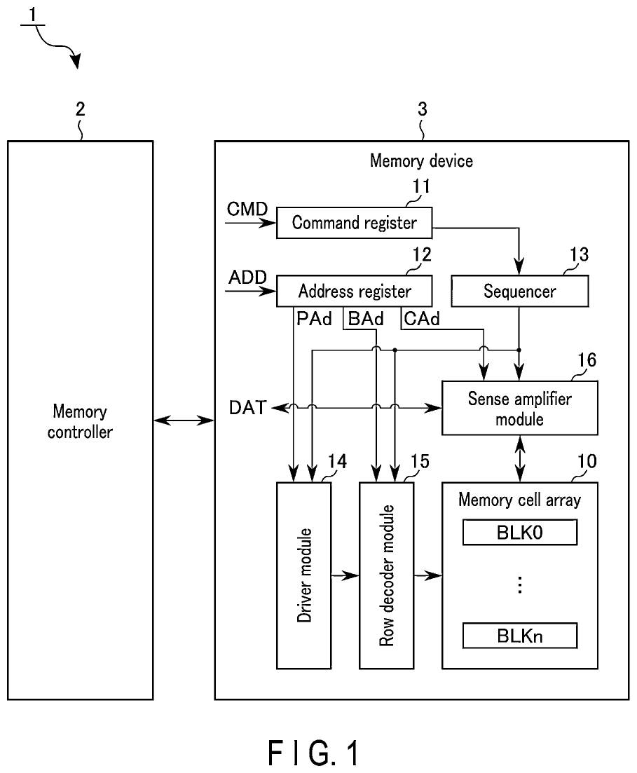

FIG. 1 is a block diagram showing an example of a configuration of a memory system including a memory device according to the embodiment. A memory system 1 is a storage device configured to be connected to an external host (not illustrated). The memory system 1 is, for example, a memory card such as an SD™ card, a universal flash storage (UFS), or a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data requested to be written by the host to the memory device 3. In addition, the memory controller 2 reads data requested to be read from the host from the memory device 3 and transmits the data to the host.

The memory device 3 is a nonvolatile memory. The memory device 3 is, for example, a NAND flash memory. The memory device 3 stores data in a nonvolatile manner.

Communication between the memory controller 2 and the memory device 3 conforms to, for example, a single data rate (SDR) interface, a toggle double data rate (DDR) interface, or an open NAND flash interface (ONFI).

### 1.2 Configuration of Memory Device

Subsequently, an internal configuration of the memory device according to the embodiment will be described with reference to the block diagram illustrated in FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer greater than or equal to 1). The number of blocks BLK included in the memory cell array 10 may be one. The block BLK is a set of a plurality of memory cells. The block BLK is used, for example, as a data erasing unit. In addition, the memory cell array 10 is provided with a plurality of bit lines and word lines. Each memory cell is associated with, for example, one bit line and one word line. A detailed configuration of the memory cell array 10 will be described later.

The command register 11 stores a command CMD that the memory device 3 receives from the memory controller 2. The command CMD includes, for example, instructions for causing the sequencer 13 to perform a read operation, write operation, erase operation, and the like.

The address register 12 stores address information ADD that the memory device 3 receives from the memory controller 2. The address information ADD includes a block address BAd, a page address PAd, and a column address CAd. For example, the block address BAd, page address PAd, and column address CAd may be used for selection of a block BLK, a word line, and a bit line, respectively.

The sequencer 13 controls the overall operation of the memory device 3. For example, the sequencer 13 controls the driver module 14, row decoder module 15, sense amplifier module 16, and the like based on the command CMD stored in the command register 11, and thereby implements the read operation, write operation, erase operation, and the like.

The driver module 14 generates a voltage to be used for the read operation, write operation, erase operation, and the like. The driver module 14 then applies the generated voltage to the signal line corresponding to the selected word line, for example based on the page address PAd stored in the address register 12.

The row decoder module 15 selects one of the blocks BLK in the corresponding memory cell array 10 based on the block address BAd stored in the address register 12. The row decoder module 15 then transfers the voltage applied to the signal line corresponding to the selected word line, to this selected word line in the selected block BLK.

In the write operation, the sense amplifier module 16 applies a desired voltage to each of the bit lines in accordance with the write data DAT received from the memory controller 2. In the read operation, the sense amplifier module 16 determines data stored in the memory cell based on the voltage of the bit line, and transfers the determination result as read data DAT to the memory controller 2.

### 1.3 Circuit Configuration of Memory Cell Array

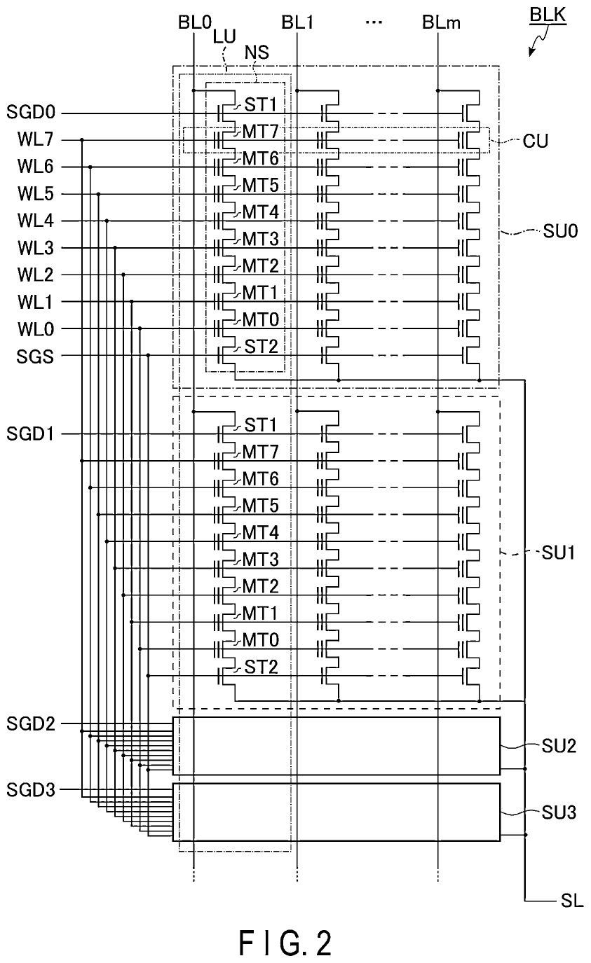

FIG. 2 is a circuit diagram showing an example of a circuit configuration of the memory cell array included in the memory device according to the embodiment. FIG. 2 illustrates one block BLK among the plurality of blocks BLK included in the memory cell array 10. As illustrated in FIG. 2, the block BLK includes, for example, four string units SU0 to SU3.

Each of the string units SU includes a plurality of NAND strings NS each associated with one of bit lines BL0 to BLm (where m is an integer greater than or equal to 1). The number of the bit lines BL may be one. Each of the NAND strings NS includes, for example, memory cell transistors MT0 to MT7 and select transistors ST1 and ST2. Each of the memory cell transistors MT includes a control gate and a charge storage portion, and stores data in a nonvolatile manner. Each of the select transistors ST1 and ST2 is used to select the string unit SU during various operations.

In each of the NAND strings NS, the memory cell transistors MT0 to MT7 are connected in series. The drain of the select transistor ST1 is connected to the associated bit line BL. The source of the select transistor ST1 is connected to one end of the memory cell transistors MT0 to MT7 that are connected in series. The drain of the select transistor ST2 is connected to the other end of the memory cell transistors MT0 to MT7 that are connected in series. The source of the select transistor ST2 is connected to a source line SL.

Within a block BLK, the control gates of the memory cell transistors MT0 to MT7 are connected to word lines WL0 to WL7, respectively. The gates of the select transistors ST1 in the string units SU0 to SU3 are connected to the select gate lines SGD0 to SGD3, respectively. The gates of the plurality of select transistors ST2 are connected to a select gate line SGS.

Different column addresses are assigned to the bit lines BL0 to BLm. Each of the bit lines BL is shared by the NAND strings NS to which the same column address is assigned across a plurality of blocks BLK. Each of the word lines WL0 to WL7 is provided for each block BLK. The source line SL is shared, for example, among a plurality of blocks BLK.

A set of a plurality of memory cell transistors MT connected to a common word line WL within one string unit SU is referred to as, for example, a cell unit CU. For example, the storage capacity of the cell unit CU including the memory cell transistors MT that each store 1-bit data is defined as 1-page data. The cell unit CU may have a storage capacity of 2-page data or more according to the number of bits of data stored by the memory cell transistor MT.

A set of the memory cell transistors MT connected to the common bit line BL within one block BLK is called, for example, a layer unit LU. One layer unit LU includes four NAND strings NS. The four NAND strings NS included in the one layer unit LU belong to the string units SU0 to SU3, respectively.

Note that the circuit configuration of the memory cell array 10 included in the memory device 3 is not limited to the above-described configuration. For example, the number of string units SU included in each block BLK may be designed to an arbitrary number. The numbers of memory cell transistors MT, and select transistors ST1 and ST2 included in each NAND string NS may be designed to arbitrary numbers.

### 1.4 Structure of Memory Cell Array

Next, a structure of the memory cell array according to the embodiment will be described.

The memory cell array 10 is provided above a substrate. Hereinafter, a plane parallel to the surface of the substrate is referred to as an XY plane. The directions intersecting each other in the XY plane are defined as an X direction and a Y direction. A direction from the substrate toward the memory cell array is defined as a Z direction. The Z direction may be read as an upward direction.

### 1.4.1 Planar Layout

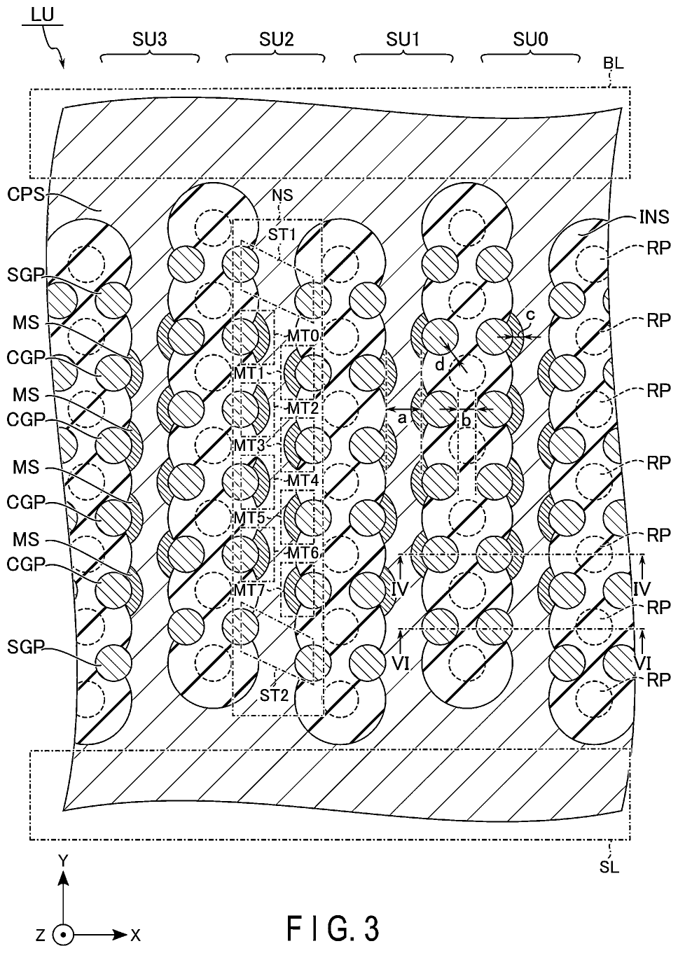

FIG. 3 is a plan view showing an example of a planar layout of the memory cell array according to the embodiment. FIG. 3 illustrates a plan view of a layer of the block BLK in which the heights from the substrate (that is, the position in the Z direction) are substantially equal. The portion illustrated in FIG. 3 corresponds to one layer unit LU in the circuit diagram illustrated in FIG. 2.

As illustrated in FIG. 3, the memory cell array 10 in a layer includes a plurality of conductive pillars CGP and SGP, a plurality of insulating pillars RP, a plurality of memory structures MS, a plurality of insulators INS, and a semiconductor CPS.

The insulator INS is an insulator extending in the Y direction. The insulator INS contains, for example, silicon oxide. In the example of FIG. 3, a case where five insulators INS are arrayed apart from each other in the X direction is illustrated.

The semiconductor CPS is a semiconductor spreading in the XY plane. The semiconductor CPS contains, for example, polysilicon. The semiconductor CPS has linear portions extending in the Y direction between two insulators INS adjacent in the X direction. In addition, the semiconductor CPS further has both end portions sandwiching the five insulators INS in the Y direction. Both end portions of the semiconductor CPS are connected via the linear portions.

The plurality of insulating pillars RP are insulators extending in the Z direction so as to intersect the corresponding insulators INS. The plurality of insulating pillars RP are provided integrally with the corresponding insulator INS. As viewed in the Z direction, each of the plurality of insulating pillars RP is entirely surrounded by the corresponding insulator INS. The plurality of insulating pillars RP intersecting the same insulator INS are arrayed in the Y direction.

Each of the plurality of conductive pillars CGP and SGP extends in the Z direction so as to intersect the insulator INS and the semiconductor CPS. Each of the plurality of conductive pillars CGP and SGP is provided at a boundary between the insulator INS and the semiconductor CPS in a region where two adjacent insulators INS face each other. That is, each of the plurality of conductive pillars CGP and SGP has a side surface facing the semiconductor CPS without interposing the insulator INS and a side surface facing the insulator INS without interposing the semiconductor CPS as viewed in the Z direction. The plurality of conductive pillars CGP and SGP are arrayed in the Y direction at the boundary between the insulator INS and the linear portion of the semiconductor CPS. In the example of FIG. 3, a case where four conductive pillars CGP are arrayed so as to be sandwiched by two conductive pillars SGP in the Y direction is illustrated. A portion where each of the plurality of conductive pillars CGP and SGP faces the semiconductor CPS functions as a transistor.

The memory structure MS is provided between the semiconductor CPS and the conductive pillar CGP and includes a charge storage film. The memory structure MS is not provided between the insulator INS and the conductive pillar CGP. That is, the memory structure MS has a fan shape as viewed in the Z direction. More specifically, the memory structure MS has a shape obtained by, from a fan shape having a radius r1 as viewed in the Z direction, removing a fan shape having a radius r2 and a central angle equivalent to that of the fan shape having the radius r1 (r1>r2). A portion where each of the plurality of conductive pillars CGP is in contact with the semiconductor CPS via the memory structure MS functions as the memory cell transistor MT. Note that the memory structure MS is not provided between the semiconductor CPS and the conductive pillar SGP. Therefore, a portion where each of the plurality of conductive pillars SGP and the semiconductor CPS are in contact with each other functions as the select transistor ST1 or ST2 instead of the memory cell transistor MT. In addition, eight sets of the conductive pillars CGP and the memory structures MS, and four conductive pillars SGP provided at the boundary between one linear portion of the semiconductor CPS and the insulator INS provided at the other end of the linear portion and the boundary between the one linear portion and the insulator INS provided at the other end of the linear portion function as one NAND string NS. In FIG. 3, the four NAND strings NS formed by the five insulators INS and the semiconductor CPS correspond to the string units SU0 to SU3, respectively.

The linear portion of the semiconductor CPS functions as a channel of the NAND string NS. One end portion of both end portions of the semiconductor CPS functions as the bit line BL. The other end portion of both end portions of the semiconductor CPS function as the source line SL.

Within a NAND string NS, two conductive pillars CGP respectively in contact with two insulators INS that face each other are separated by a length “a” in the X direction. Two conductive pillars CGP that are in contact with the same insulator INS and belong to different NAND strings NS are separated by a length “b” in the X direction. The memory structure MS has a length “c” (=r1−r2) in the radial direction of the corresponding conductive pillar CGP. In other words, the semiconductor CPS and the conductive pillar CGP are separated by the length “c” in the X direction via the memory structure MS. The conductive pillar CGP and the insulating pillar RP that are in contact with the same insulator INS and are adjacent to each other are separated by a length “d”.

The length “a” and the length “b” may be different. More specifically, the length “a” is preferably longer than the length “b” (a>b). In addition, the length “b” may be shorter than twice the length “c” (b<2c). The length “d” may be shorter than the length “c” (d<c).

### 1.4.2 Cross-Sectional Structure of Conductive Pillar CGP

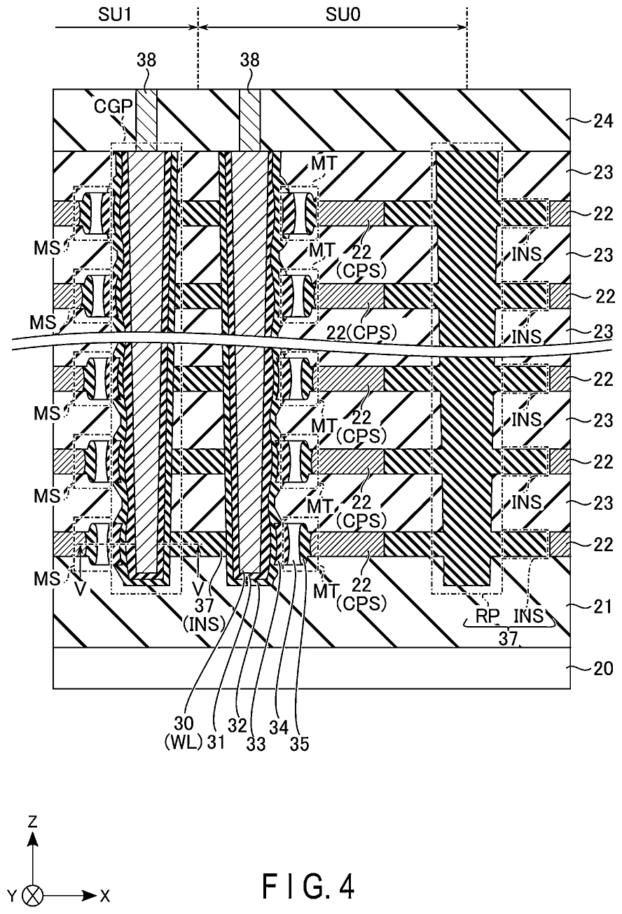

FIG. 4 is a cross-sectional view taken along line IV-IV of FIG. 3, showing an example of a cross-sectional structure of the memory cell array according to the embodiment. FIG. 4 mainly illustrates a cross-sectional structure of two conductive pillars CGP in contact with a first insulator INS and one insulating pillar RP provided in a second insulator INS adjacent to the first insulator INS.

As illustrated in FIG. 4, the memory cell array 10 includes a substrate 20, insulating layers 21, 23, and 24, a semiconductor layer 22, an insulator 37, a conductor 38, the conductive pillars CGP, and the memory structure MS. The insulator 37 includes a portion corresponding to the insulating pillar RP and a portion corresponding to the insulator INS.

The substrate 20 is, for example, a P-type semiconductor. The insulating layer 21 is provided on the upper surface of the substrate 20. The substrate 20 and the insulating layer 21 may include a circuit (not illustrated). The circuits included in the substrate 20 and the insulating layer 21 correspond to, for example, the row decoder module 15, the sense amplifier module 16, and the like.

On the upper surface of the insulating layer 21, a plurality of semiconductor layers 22 and a plurality of insulating layers 23 are alternately stacked one by one. In the example of FIG. 4, five semiconductor layers 22 and five insulating layers 23 are alternately stacked one by one. In other words, a plurality of semiconductor layers 22 stacked apart in the Z direction are provided above the substrate 20. The number of stacked semiconductor layers 22 corresponds to, for example, the number of bit lines BL.

The semiconductor layer 22 corresponds to the semiconductor CPS and has a portion extending in the Y direction. The portion extending in the Y direction of the semiconductor layer 22 (that is, the portion illustrated in FIG. 4) functions as the channel of the NAND string NS. The insulating layers 21 and 23 contain, for example, silicon oxide. The semiconductor layer 22 contains, for example, polysilicon.

The insulating layer 24 is provided on the upper surface of the uppermost insulating layer 23. The insulating layers 24 contains, for example, silicon oxide.

The insulator 37 has a portion extending in the Z direction, and the portion corresponds to the insulating pillar RP. The insulating pillar RP intersects the plurality of semiconductor layers 22 and the insulating layer 23. The lower end of the insulating pillar RP reaches the insulating layer 21. The upper end of the insulating pillar RP is aligned with, for example, the upper end of the uppermost insulating layer 23.

The insulator 37 has a portion spreading in the XY plane in the same layer as that of the semiconductor layer 22, and the portion corresponds to the insulator INS. The insulator INS and the insulating pillar RP are provided as a continuous film.

The conductive pillar CGP extends in the Z direction so as to intersect the plurality of semiconductor layers 22 and insulating layers 23. The lower end of the conductive pillar CGP reaches the insulating layer 21. The upper end of the conductive pillar CGP is aligned with, for example, the upper end of the uppermost insulating layer 23. The conductive pillar CGP functions as the word line WL by being electrically connected to the row decoder module 15 via the conductor 38 provided in the insulating layer 24.

In the same layer as that of the semiconductor layer 22, a part of the side surface of the conductive pillar CGP is in contact with the insulator INS. In the same layer as that of the semiconductor layer 22, a portion of the side surface of the conductive pillar CGP not in contact with the insulator INS is in contact with the memory structure MS. The conductive pillar CGP includes a conductive film 30 and insulating films 31 and 32. The memory structure MS includes an insulating film 33, a charge storage film 34, and an insulating film 35.

The conductive film 30 extends in the Z direction. For example, the upper end of the conductive film 30 is in contact with the conductor 38. The lower end of the conductive film 30 is included in a layer below the lowermost semiconductor layer 22. The conductive film 30 contains, for example, titanium nitride.

The insulating film 31 covers the periphery of the portion excluding the upper surface of the conductive film 30. The insulating film 32 covers the periphery of the insulating film 31. The insulating film 31 contains, for example, aluminum oxide. The insulating film 32 contains, for example, silicon oxide.

The insulating film 33 covers a part of the side surface of the insulating film 32 in the same layer as that of the semiconductor layer 22. The charge storage film 34 covers the side surface of the insulating film 33. The insulating film 35 covers the side surface of the charge storage film 34. The side surface of the insulating film 35 is covered with the semiconductor layer 22. The insulating film 33 contains, for example, hafnium silicate. The insulating film 35 contains, for example, silicon oxide. The charge storage film 34 contains a material having a function of storing charges. Specifically, the charge storage film 34 may contain, for example, a conductor such as silicon or metal. In addition, the charge storage film 34 may contain an insulator such as silicon nitride, for example. In a case where the charge storage film 34 contain a conductor such as silicon or metal, the memory cell transistor MT functions as a floating gate type memory cell transistor MT. In a case where the charge storage film 34 contains an insulator such as silicon nitride, the memory cell transistor MT functions as a metal-oxide-nitride-oxide-silicon (MONOS) type memory cell transistor MT.

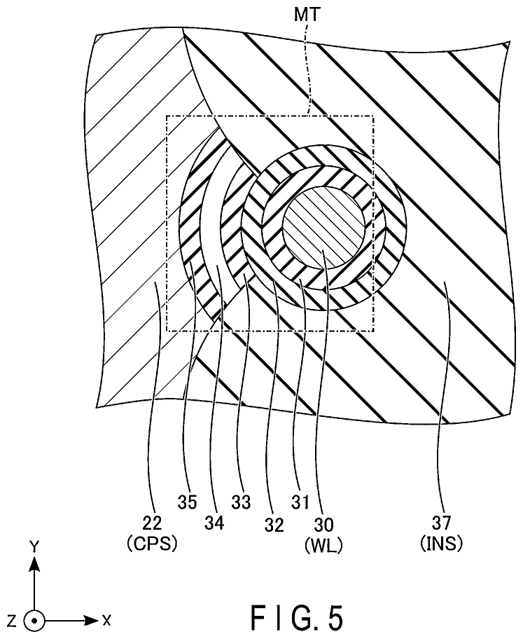

FIG. 5 is a cross-sectional view taken along line V-V of FIG. 4, showing an example of a cross-sectional structure of the memory cell transistor according to the embodiment. More specifically, FIG. 5 illustrates a cross-sectional structure of the conductive pillar CGP in a layer that is parallel to the XY plane and includes semiconductor layer 22.

In the cross section including the semiconductor layer 22, the conductive film 30 is provided, for example, at the central portion of the conductive pillar CGP. The insulating film 31 surrounds the side surface of the conductive film 30. The insulating film 32 surrounds the side surface of the insulating film 31. The insulating film 33 surrounds a portion of the side surface of the insulating film 32 that is not in contact with the insulator INS. The charge storage film 34 surrounds the side surface of the insulating film 33. The insulating film 35 surrounds the side surface of the charge storage film 34. The semiconductor layer 22 surrounds the side surface of the insulating film 35. In this manner, the insulating film 33, the charge storage film 34, and the insulating film 35 are provided only between the conductive pillar CGP and the semiconductor layer 22, and are not provided between the conductive pillar CGP and the insulator INS.

The conductive film 30 is used as a wiring (word line WL) connected to the gates of the memory cell transistors MT. The insulating films 31, 32, and 33 are used as block insulating films of the memory cell transistors MT. The insulating film 35 is used as a tunnel insulating film of the memory cell transistor MT. As a result, the conductive pillar CGP may function as the plurality of memory cell transistors MT connected to the same word line WL. In other words, the conductive pillar CGP may function as at least a portion of one cell unit CU.

### 1.4.3 Cross-Sectional Structure of Conductive Pillar SGP

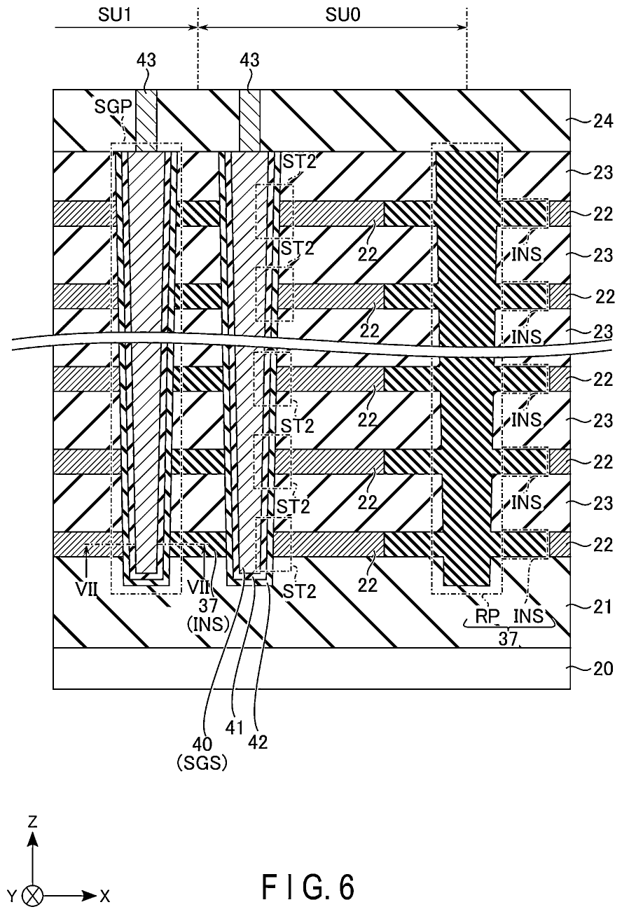

FIG. 6 is a cross-sectional view taken along line VI-VI of FIG. 3, showing an example of a cross-sectional structure of the memory cell array according to the embodiment. FIG. 6 mainly illustrates a cross-sectional structure of two conductive pillars SGP in contact with a first insulator INS and one insulating pillar RP provided in a second insulator INS adjacent to the first insulator INS.

As illustrated in FIG. 6, the memory cell array 10 further includes a conductor 43 and conductive pillars SGP. Structures other than the conductor 43 and the conductive pillars SGP are equivalent to the structure illustrated in FIG. 4, and thus description thereof is omitted.

The conductive pillar SGP extends in the Z direction so as to intersect the plurality of semiconductor layers 22 and insulating layers 23. The lower end of the conductive pillar SGP reaches the insulating layer 21. The upper end of the conductive pillar SGP is aligned with, for example, the upper end of the uppermost insulating layer 23. The conductive pillar SGP functions as the select gate line SGS by being electrically connected to the row decoder module 15 via the conductor 43 provided in the insulating layer 24.

In the same layer as that of the semiconductor layer 22, a part of the side surface of the conductive pillar SGP is in contact with the insulator INS. In the same layer as that of the semiconductor layer 22, a portion of the side surface of the conductive pillar SGP not in contact with the insulator INS is in contact with the semiconductor layer 22. The conductive pillar SGP includes a conductive film 40 and insulating films 41 and 42.

The conductive film 40 extends in the Z direction. For example, the upper end of the conductive film 40 is in contact with the conductor 43. The lower end of the conductive film 40 is included in a layer below the lowermost semiconductor layer 22. The conductive film 40 contains, for example, titanium nitride.

The insulating film 41 covers the periphery of the portion excluding the upper surface of the conductive film 40. The insulating film 42 covers the periphery of the insulating film 41. The insulating film 41 contains, for example, aluminum oxide. The insulating film 42 contains, for example, silicon oxide.

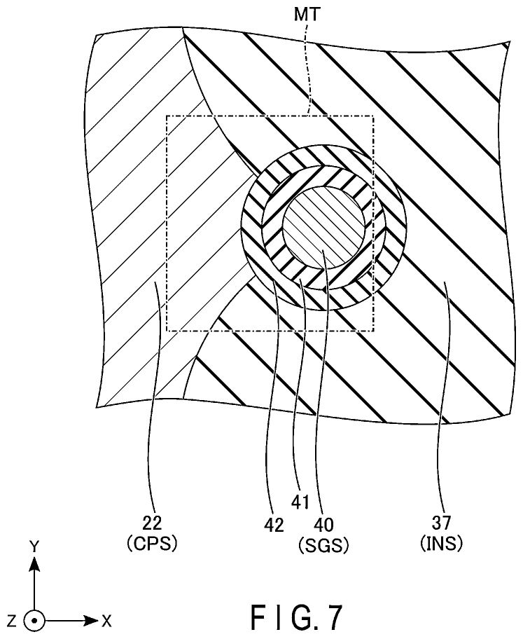

FIG. 7 is a cross-sectional view taken along line VII-VII of FIG. 6, showing an example of a cross-sectional structure of a select transistor according to the embodiment. More specifically, FIG. 7 illustrates a cross-sectional structure of the conductive pillar SGP in a layer that is parallel to the XY plane and includes semiconductor layer 22.

In the cross section including the semiconductor layer 22, the conductive film 40 is provided, for example, at the central portion of the conductive pillar SGP. The insulating film 41 surrounds the side surface of the conductive film 40. The insulating film 42 surrounds the side surface of the insulating film 41. The semiconductor layer 22 surrounds a part of the side surface of the insulating film 42. A portion of the side surface of the insulating film 42 that is not surrounded by the semiconductor layer 22 is surrounded by the insulator 37.

The conductive film 40 is used as wiring (select gate line SGS) connected to the gates of the select transistors ST2. The insulating films 41 and 42 are used as block insulating films of the select transistor ST2. As a result, the conductive pillar SGP may function as a plurality of select transistors ST2 connected to the same select gate line SGS.

Note that, in FIGS. 6 and 7, the cross-sectional structure of the conductive pillar SGP corresponding to the select gate line SGS has been described, but the conductive pillar SGP corresponding to the select gate line SGD also has a cross-sectional structure equivalent to that of the conductive pillar SGP corresponding to the select transistor ST2.

### 1.2 Manufacturing Method

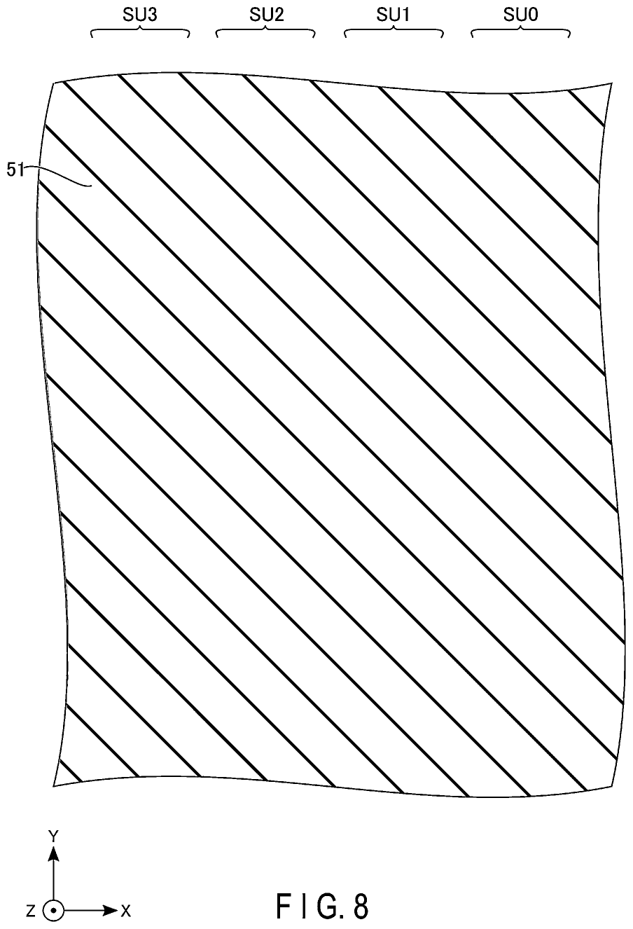

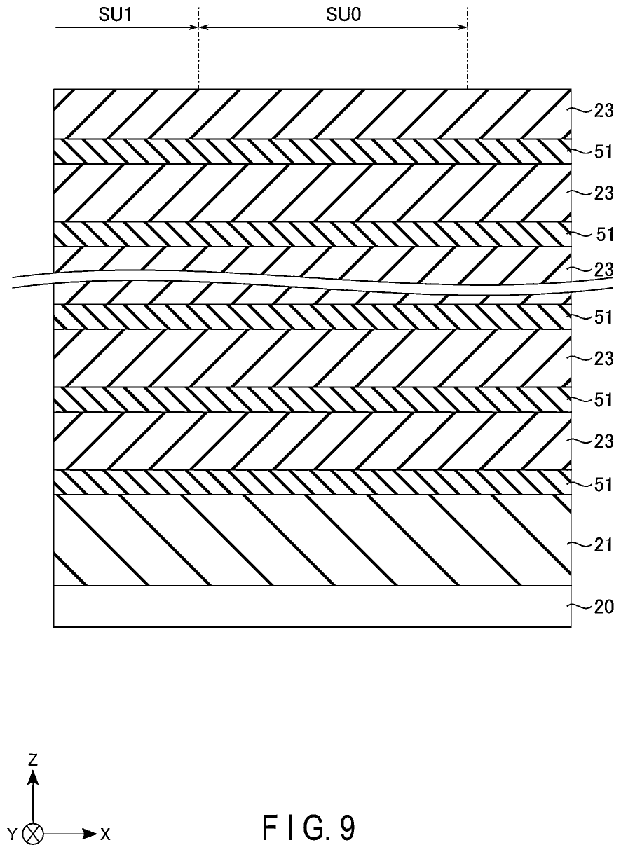

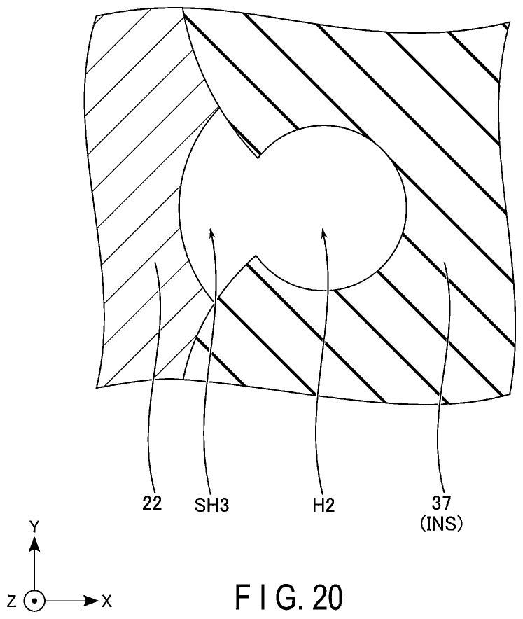

FIGS. 8, 10, 12, 14, 16, 18, 20, 22, 24, and 26 are plan views showing an example of a planar layout of the memory device according to the embodiment that is in the process of being manufactured. FIGS. 9, 11, 13, 15, 17, 19, 21, 23, 25, and 27 are cross-sectional views showing an example of a cross-sectional structure of the memory device according to the embodiment that is in the process of being manufactured. FIGS. 8, 10, 12, 14, 16, and 18 correspond to the planar layout illustrated in FIG. 3. FIGS. 20, 22, 24, and 26 correspond to the planar layout illustrated in FIG. 5. FIGS. 9, 11, 13, 15, 17, 19, 21, 23, 25, and 27 correspond to the cross section illustrated in FIG. 4.

First, as illustrated in FIGS. 8 and 9, a stacked structure is formed on the upper surface of the substrate 20. Specifically, the insulating layer 21 is provided on the upper surface of the substrate 20. Subsequently, a sacrificial member 51 and the insulating layer 23 are repeatedly stacked in this order on the upper surface of the insulating layer 21. The sacrificial member 51 contains, for example, silicon nitride.

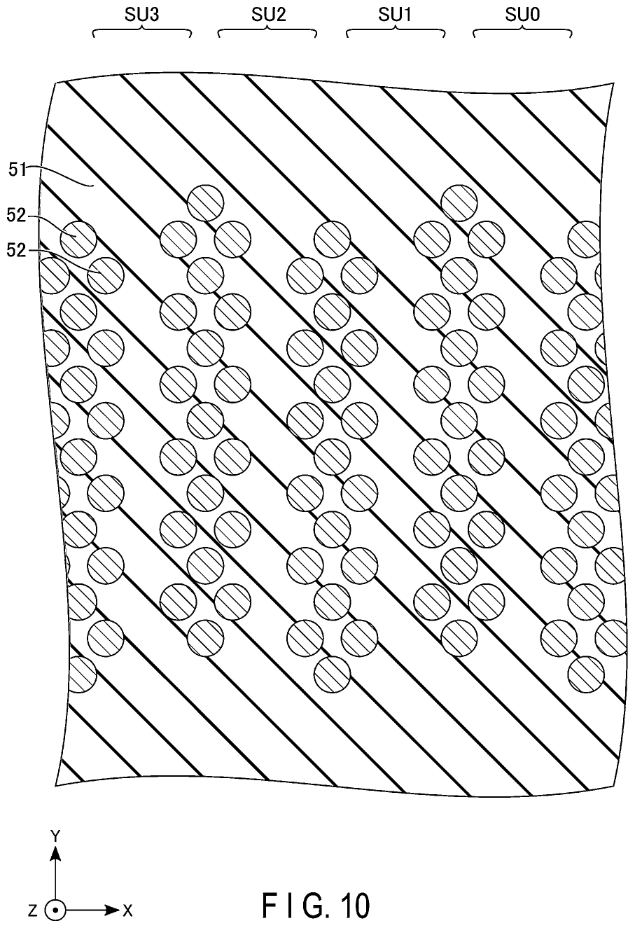

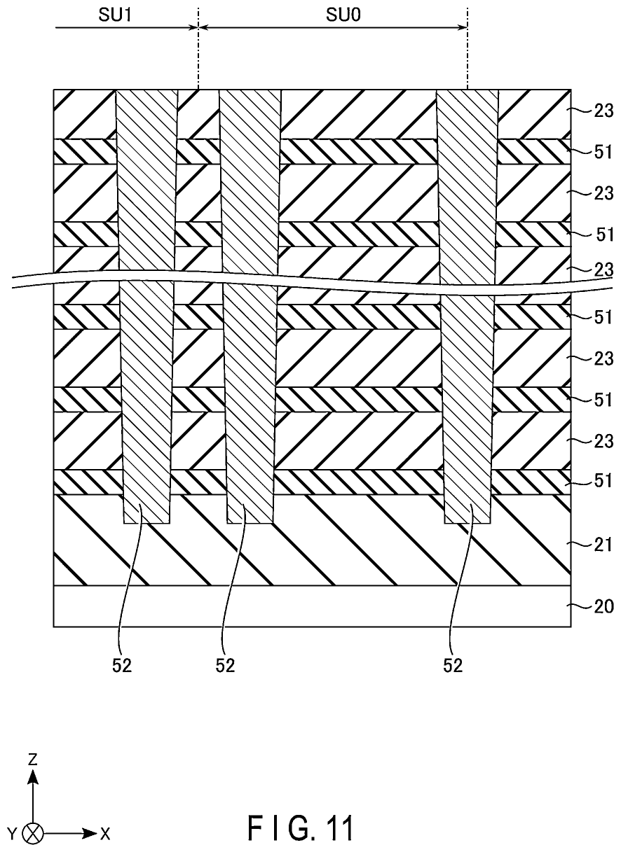

Next, as illustrated in FIGS. 10 and 11, a plurality of holes are provided in a region of the stacked structure where the plurality of insulating pillars RP and the plurality of conductive pillars CGP and SGP are to be provided. Each of the plurality of holes penetrates the plurality of sacrificial members 51 and insulating layers 23. The bottom of each of the plurality of holes reaches the insulating layer 21. Each of the plurality of holes is filled with a sacrificial member 52. The sacrificial member 52 contains, for example, amorphous silicon.

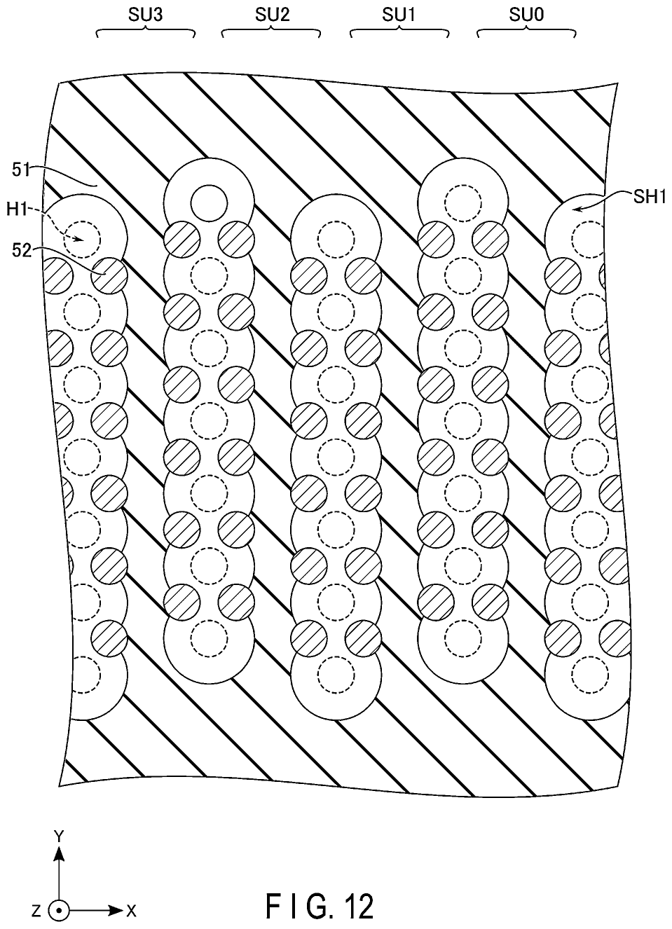

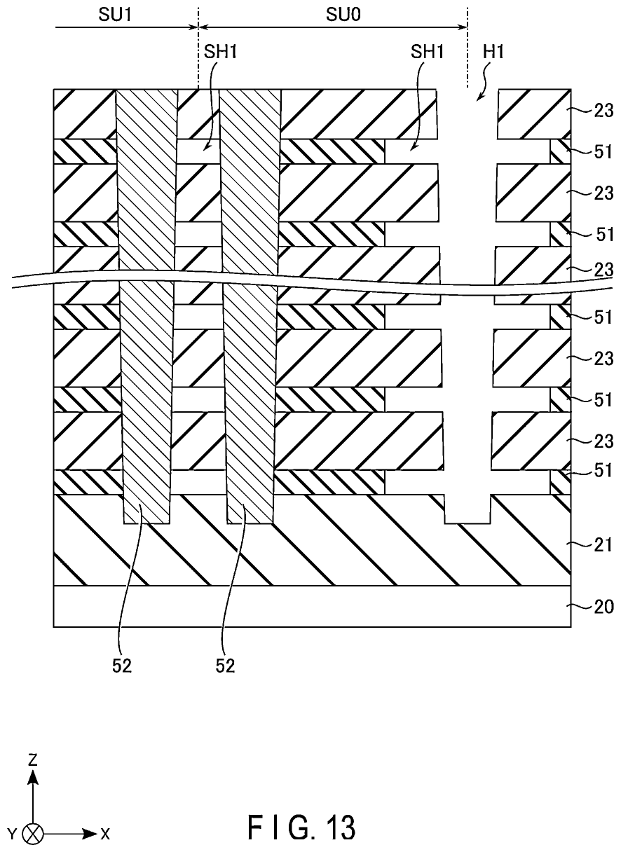

Next, as illustrated in FIGS. 12 and 13, the sacrificial members 52 corresponding to the insulating pillars RP among the plurality of sacrificial members 52 are removed to form a plurality of holes H1. As a result, the plurality of sacrificial members 51 stacked apart from each other are exposed inside the plurality of holes H1. Thereafter, for example, a portion of the sacrificial member 51 where the insulator INS is to be provided is selectively removed from the plurality of holes H1 by wet etching. As a result, grooves SH1 each spreading in the XY plane from the inside of the plurality of holes H1 are formed.

Within a layer, two grooves SH1 corresponding to each of the holes H1 adjacent to each other in the Y direction are connected. That is, the plurality of holes H1 arrayed in the Y direction are spatially connected via the groove SH1. On the other hand, two grooves SH1 corresponding to each of the holes H1 adjacent to each other in the X direction are not connected. That is, the plurality of holes H1 arrayed in the X direction are separated by the sacrificial member 51. In addition, the groove SH1 exposes a part of the side surface of the sacrificial member 52 in a layer. That is, although a part of the side surface of the sacrificial member 52 in the layer in which the sacrificial member 51 is provided is exposed after the formation of the groove SH1, the sacrificial member 52 still has a side surface covered with the sacrificial member 51.

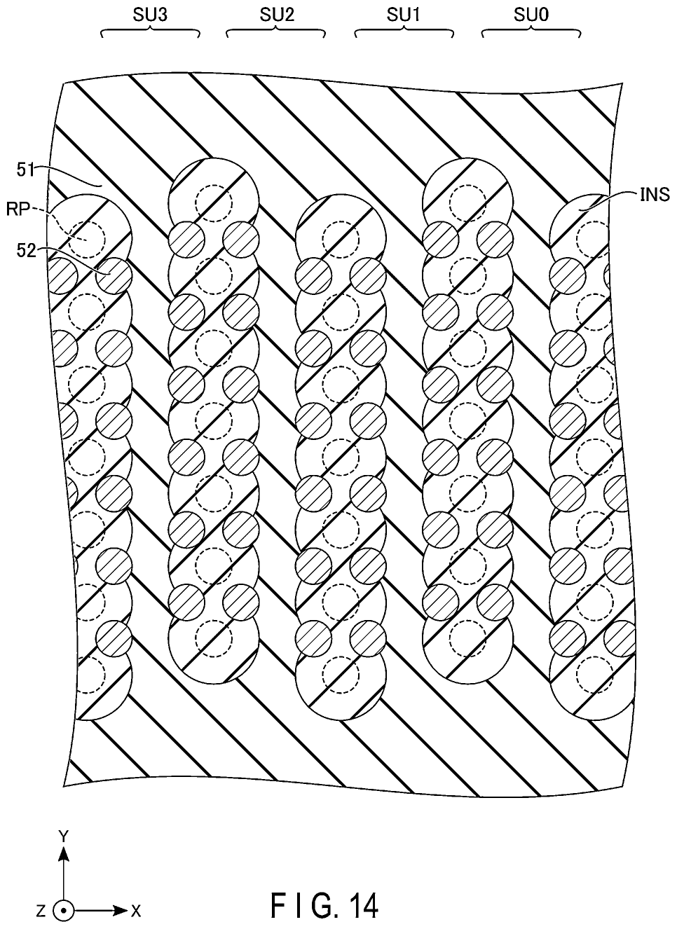

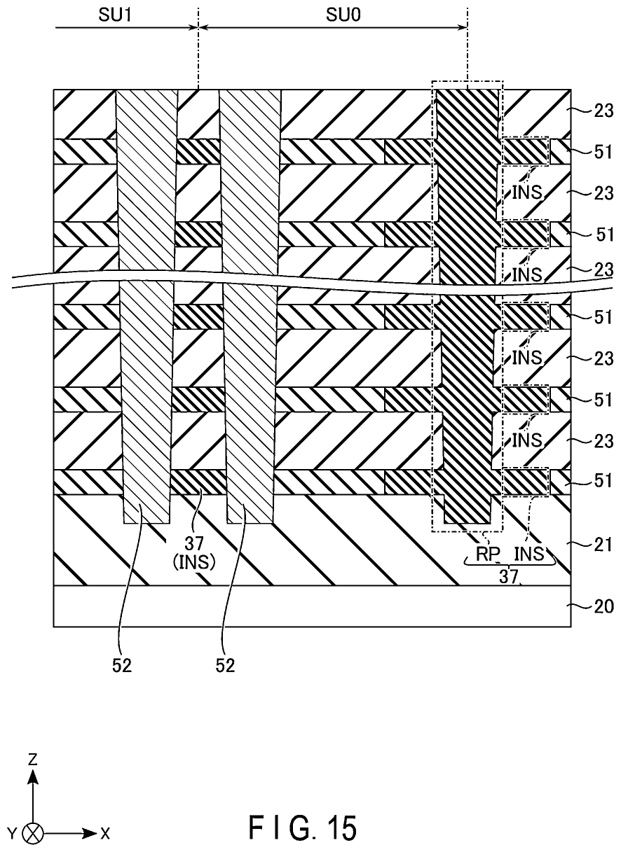

Next, as illustrated in FIGS. 14 and 15, a plurality of grooves SH1 and the plurality of holes H1 are filled with the insulator 37. Thus, the plurality of insulators INS and the plurality of insulating pillars RP are formed.

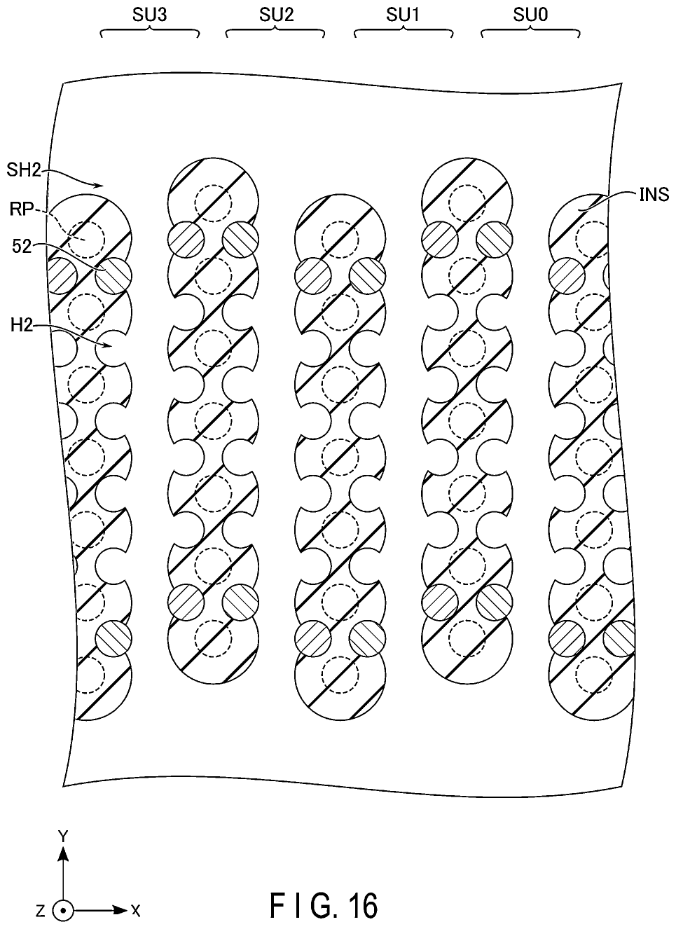

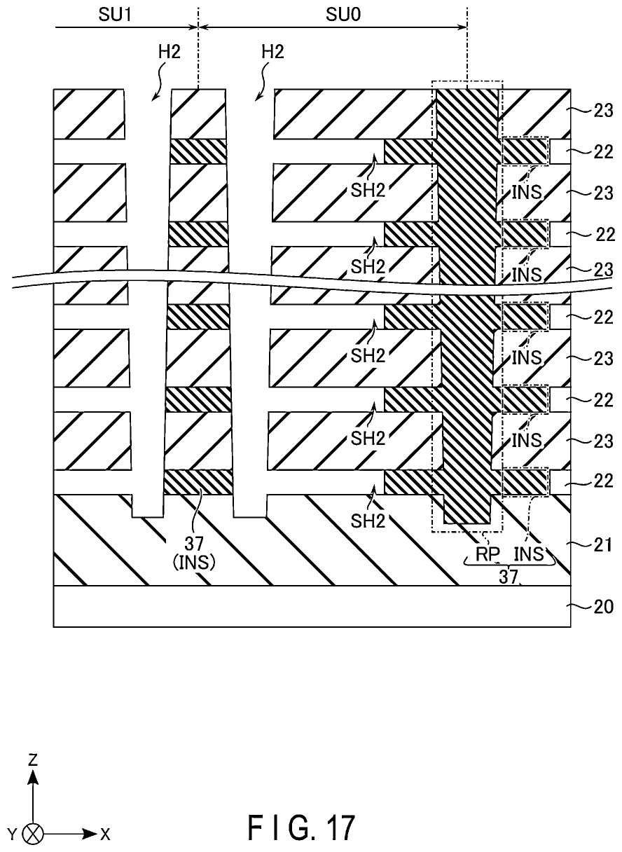

Next, as illustrated in FIGS. 16 and 17, the sacrificial members 52 corresponding to the conductive pillars CGP among the plurality of sacrificial members 52 are removed to form a plurality of holes H2. As a result, the plurality of sacrificial members 51 stacked apart from each other are exposed inside the plurality of holes H2. Thereafter, for example, all the sacrificial members 51 (that is, a portion where the semiconductor CPS is to be provided) are selectively removed from the plurality of holes H2 by wet etching. As a result, grooves SH2 each spreading in the XY plane from the inside of the plurality of holes H2 are formed.

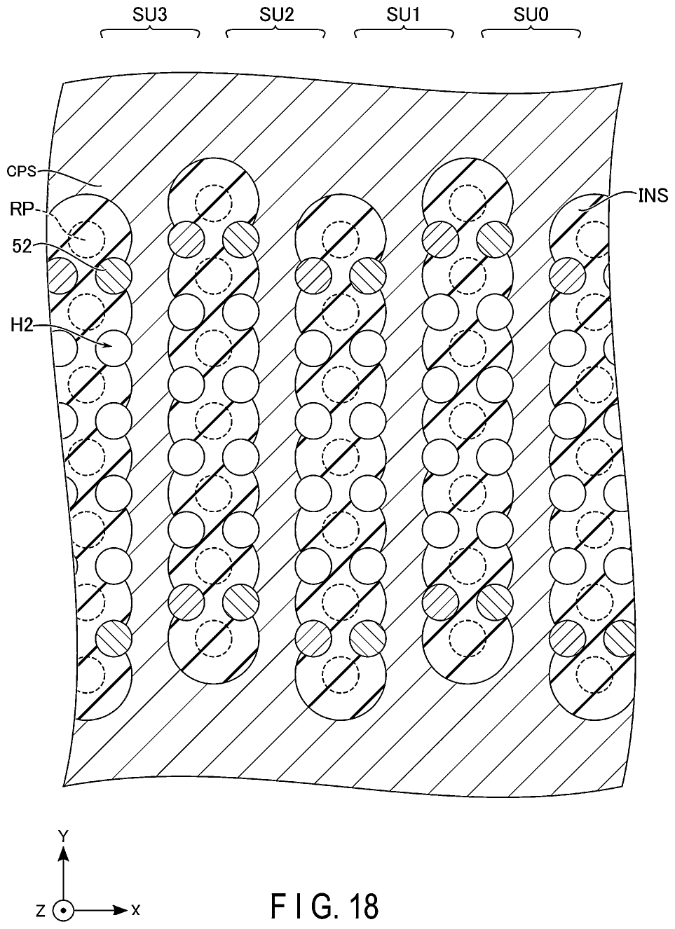

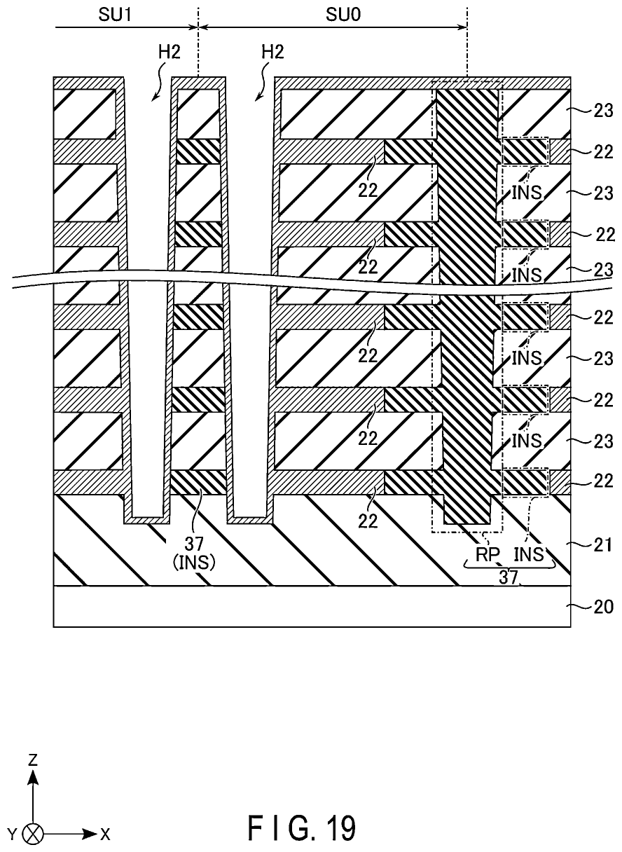

Next, as illustrated in FIGS. 18 and 19, a plurality of grooves SH2 and a part of the plurality of holes H2 are filled with the semiconductor CPS.

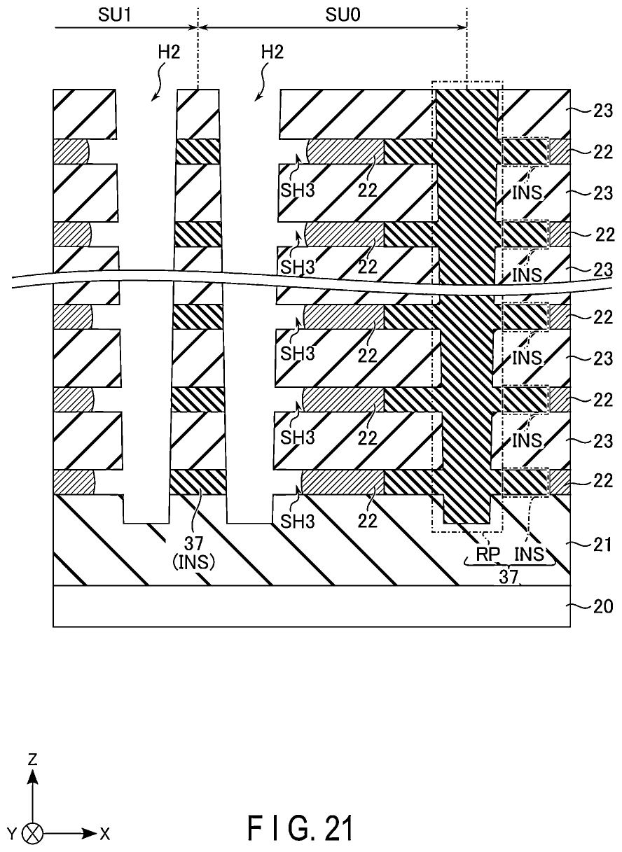

Next, as illustrated in FIGS. 20 and 21, the semiconductor CPS is partially removed by, for example, wet etching. As a result, a portion of the semiconductor CPS that is formed in the plurality of grooves SH2 are separated from each other to form a plurality of semiconductor layers 22, and a plurality of grooves SH3 are formed in a region where a plurality of memory structures MS are to be formed.

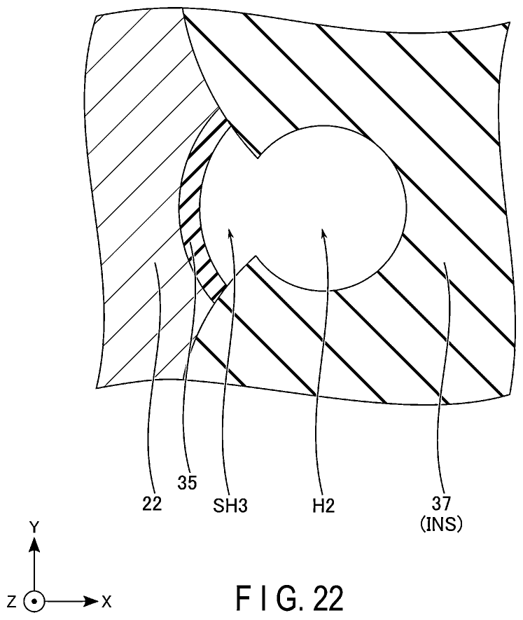

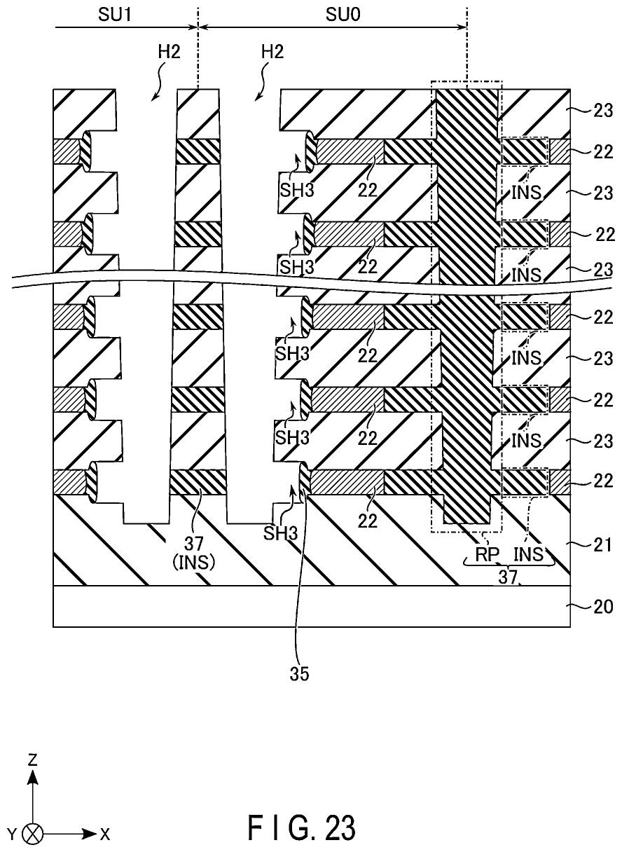

Next, as illustrated in FIGS. 22 and 23, a part of the plurality of insulating layer 23 is selectively removed by, for example, wet etching. As a result, the plurality of grooves SH3 expands in the Z direction. Thereafter, the insulating film 35 is formed in a portion of each of the plurality of grooves SH3 that is in contact with the semiconductor layer 22.

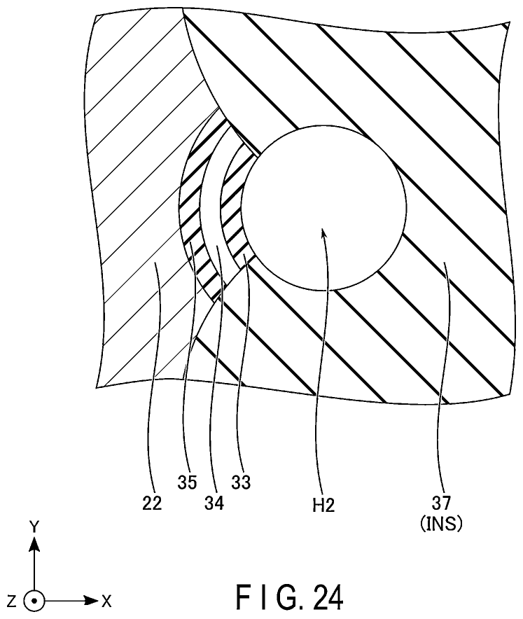

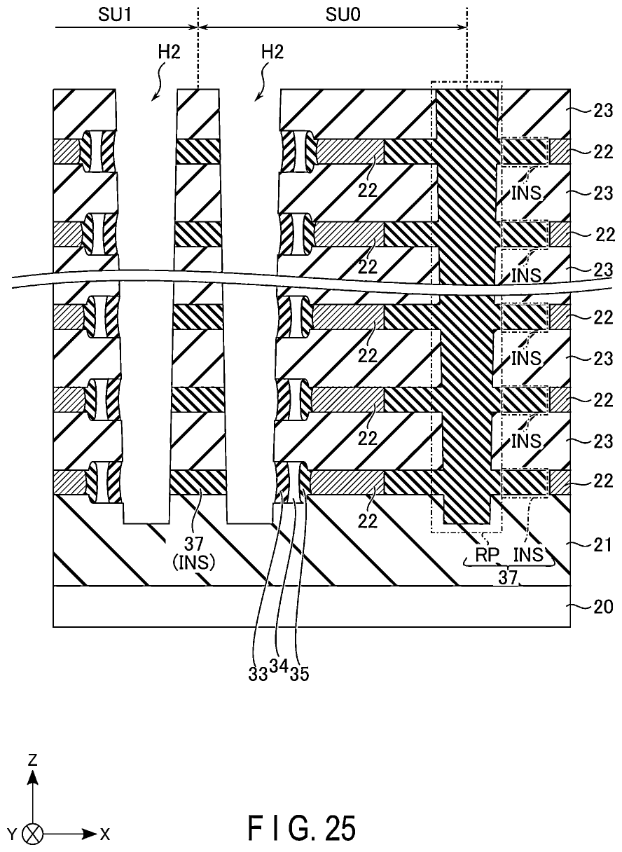

Next, as illustrated in FIGS. 24 and 25, the charge storage film 34 is formed in a portion of each of the plurality of grooves SH3 that is in contact with the insulating film 35. Then, the insulating film 33 is formed in a portion of each of the plurality of grooves SH3 that is in contact with the charge storage film 34. As a result, the plurality of grooves SH3 are filled.

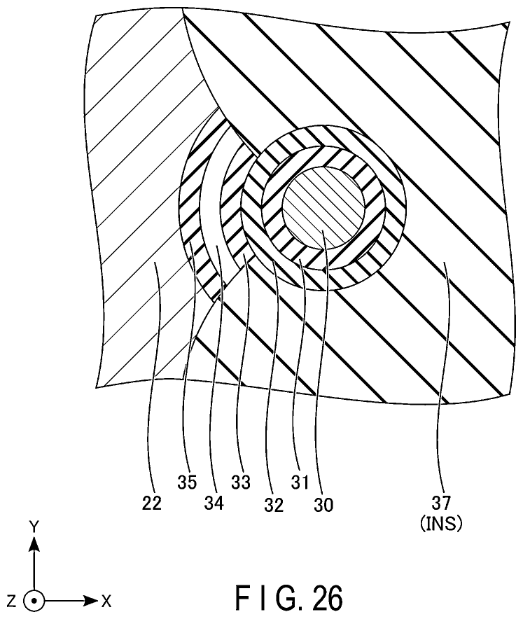

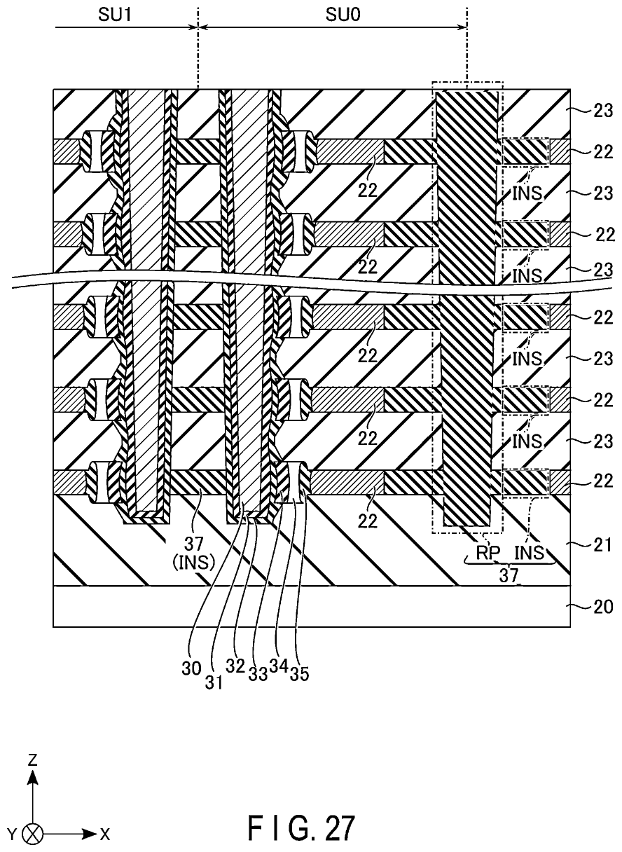

Next, as illustrated in FIGS. 26 and 27, a part of the plurality of insulating layer 23 is selectively removed by, for example, wet etching. Thereafter, the insulating film 32, the insulating film 31, and the conductive film 30 are formed in this order inside the plurality of holes H2 to fill the plurality of holes H2.

Thereafter, the sacrificial member 52 corresponding to the conductive pillar SGP is removed to form a plurality of holes. Then, the insulating film 42, the insulating film 41, and the conductive film 40 are formed in this order in the hole to fill the hole, thereby forming the plurality of conductive pillars SGP.

Thereafter, a structure above the stacked structure of the memory cell array 10 is formed. Thus, the memory device 3 is formed.

### 1.3 Effects According to Embodiment

According to the embodiment, the semiconductor CPS is formed after the insulator INS is formed. Inside the hole H2 corresponding to the conductive pillar CGP, a first portion where the semiconductor CPS is exposed and a second portion where the insulator is exposed are formed in a layer. The memory structure MS is formed by replacing a part of the semiconductor CPS via the hole H2. This enables a configuration such that the memory structure MS is provided between the first portion of the hole H2 and the semiconductor CPS and not provided between the second portion of the hole H2 and the insulator INS. That is, this enables a configuration such that the memory structure MS is not to be provided between two conductive pillars CGP arrayed in the X direction via the insulator INS. Due to this, the length “b” between the two conductive pillars CGP arrayed in the X direction via the insulator INS can be made shorter than twice the length “c” of the memory structure MS. Therefore, the integration level of the memory cell array 10 can be improved as compared with a case where the memory structure MS is provided so as to surround the conductive pillars CGP as viewed in the Z direction.

### 2. Modifications

Note that various modifications can be applied to the above-described embodiment.

In the above-described embodiment, the case where a plurality of conductive pillars CGP belonging to a string unit SU and a plurality of conductive pillars CGP belonging to a string unit SU adjacent to the string unit SU are arranged in a zigzag shape as viewed in the Z direction has been described, but the present invention is not limited thereto. For example, the plurality of conductive pillars CGP may be arranged in a matrix as viewed in the Z direction.

In addition, in the above-described embodiment, the case where the conductive pillars CGP and SGP and the insulating pillar RP are circular as viewed in the Z direction has been described, but the present invention is not limited thereto. For example, the conductive pillars CGP and SGP and the insulating pillar RP may have a shape other than a circular shape such as an ellipse or a polygon as viewed in the Z direction.

In addition, in the above-described embodiment, the case where the conductive pillars SGP are formed after the conductive pillars CGP are formed has been described, but the present invention is not limited thereto. For example, the conductive pillars SGP may be formed after the insulator INS is formed and before the conductive pillars CGP are formed.

In addition, in the above-described embodiment, the case where the memory structure MS is not provided between the conductive pillar SGP and the semiconductor CPS has been described, but the present invention is not limited thereto. For example, a structure equivalent to the memory structure MS provided between the conductive pillar CGP and the semiconductor CPS may be provided between the conductive pillar SGP and the semiconductor CPS. In this case, the conductive pillar SGP is manufactured in the same process as that of the conductive pillar CGP. Even in a case where the memory structure MS is provided between the conductive pillar SGP and the semiconductor CPS, the conductive pillar SGP and the semiconductor CPS can function as the select transistor ST1 or ST2.

While certain embodiments have been described, these embodiments have been presented by way of example only, and are not intended to limit the scope of the invention. Indeed, the embodiments described herein may be embodied in a variety of other forms; furthermore, various omissions, substitutions and changes in the form of the embodiments described herein may be made without departing from the spirit of the inventions. The embodiments and modifications are included in the scope and spirit of the invention and are included in the scope of the claimed inventions and their equivalents.

What is claimed is:

1. A memory device comprising:
a first semiconductor and a first insulator provided at a first position in a first direction intersecting a substrate;
a first conductor extending in the first direction and having a first portion facing the first semiconductor without interposing the first insulator and a second portion facing the first insulator without interposing the first semiconductor; and
a first charge storage film provided between the first portion and the first semiconductor and not provided between the second portion and the first insulator.

2. The memory device according to claim 1, wherein
the first semiconductor and the first insulator
extend in a second direction intersecting the first direction, and
are arranged in a third direction intersecting the first direction and the second direction.

3. The memory device according to claim 2, further comprising:
a second semiconductor provided on a side opposite to the first semiconductor with respect to the first insulator at the first position;
a second conductor extending in the first direction and having a third portion facing the second semiconductor without interposing the first insulator and a fourth portion facing the first insulator without interposing the second semiconductor; and
a second charge storage film provided between the third portion and the second semiconductor and not provided between the fourth portion and the first insulator.

4. The memory device according to claim 3, wherein
a length in the third direction between the first conductor and the second conductor is shorter than twice a length in the third direction between the first conductor and the first semiconductor.

5. The memory device according to claim 3, further comprising:
a second insulator provided on a side opposite to the first insulator with respect to the first semiconductor at the first position;
a third conductor extending in the first direction and having a fifth portion facing the first semiconductor without interposing the second insulator and a sixth portion facing the second insulator without interposing the first semiconductor; and
a third charge storage film provided between the fifth portion and the first semiconductor and not provided between the sixth portion and the second insulator.

6. The memory device according to claim 5, wherein
a length in the third direction between the first conductor and the third conductor is longer than a length in the third direction between the first conductor and the second conductor.

7. The memory device according to claim 3, wherein
the first semiconductor and the second semiconductor are provided as a continuous film.

8. The memory device according to claim 2, further comprising:
a fourth conductor extending in the first direction, having a seventh portion facing the first semiconductor without interposing the first insulator and an eighth portion facing the first insulator without interposing the first semiconductor, and arranged in the second direction together with the first conductor; and
a fourth charge storage film provided between the seventh portion and the first semiconductor and not provided between the eighth portion and the first insulator.

9. The memory device according to claim 1, further comprising:
a third semiconductor and a third insulator provided at a second position different from the first position in the first direction, wherein
the first conductor further has a ninth portion facing the third semiconductor without interposing the third insulator and a tenth portion facing the third insulator without interposing the third semiconductor; and
a fifth charge storage film provided between the ninth portion and the third semiconductor and not provided between the tenth portion and the third insulator.

10. The memory device according to claim 1, wherein
the first charge storage film contains silicon nitride.

11. The memory device according to claim 1, wherein
the first charge storage film contains silicon or metal.

12. The memory device according to claim 1, wherein
the first charge storage film has a fan shape as viewed in the first direction.
